(19) United States
(12) Patent Application Publication
(10) Pub. No.: US 2003/0036273 A1
(43) Pub. Date: Feb. 20, 2003

(54) Shield for capturing fluid displaced from a substrate

(75) Inventor: Bernardo Donoso, San Jose, CA (US)

Correspondence Address: PATENT COUNSEL, APPLIED MATERIALS, INC., Legal Affairs Department, P.O. BOX 450A, Santa Clara, CA, 95052, US

(73) Assignee: Applied Materials, Inc.

(21) Appl. No.: 10/219,198

(22) Filed: Aug. 13, 2002

Related U.S. Application Data
(60) Provisional application No. 60/312,337, filed on Aug. 14, 2001.

(51) Int. Cl. H01L 21/302; H01L 21/461

(52) U.S. Cl. 438/692

(57) ABSTRACT

In a first aspect, a system is provided that includes (1) a substrate support adapted to hold and rotate a substrate; (2) a source of fluid adapted to supply fluid to a surface of a substrate held by the substrate support; and (3) a shield positioned to capture fluid supplied by the source of fluid and displaced from a substrate held and rotated by the substrate support. The shield includes a radiused surface adapted to carry the captured fluid away from the substrate held by the substrate support. Apparatus and methods in accordance with this and other aspects also are provided.

This application claims priority from U.S. Provisional Patent Application Serial No. 60/312,337, filed Aug. 14, 2001, which is hereby incorporated by reference herein in its entirety.

### FIELD OF THE INVENTION

The present invention relates to processing substrates such as glass substrates, flat panel displays, patterned or unpatterned semiconductor substrates and the like. More specifically, the present invention relates to capturing fluid displaced from a substrate during processing.

### BACKGROUND OF THE INVENTION

The use of copper rather than aluminum metal layers in semiconductor integrated circuits has introduced several integration challenges for the semiconductor industry. One such challenge is the inability of chemical mechanical polishing (CMP) techniques to remove copper from the edge bevel of a semiconductor substrate. Copper residing on an edge bevel of a substrate may create a short circuit between the substrate's frontside (e.g., where integrated circuits reside) and the substrate's backside (e.g., which typically is grounded). This type of short circuit may damage or otherwise render inoperative the integrated circuits residing on the substrate's frontside, and must be removed.

One technique for removing copper from an edge bevel of a semiconductor substrate is to dispense a stream of etching solution directly on the device side of the substrate (e.g., on the edge bevel from which copper is to be removed). During this type of edge bevel cleaning operation, a substrate typically is rotated at a controlled speed. As the etching solution strikes the edge bevel of the rotating substrate, the etching solution is forced radially away from the substrate's device containing surfaces due to the centrifugal force generated by rotating the substrate. After being displaced from the rotating substrate, the etching solution may splash against chamber surfaces and create an etchant mist that can attack and damage the integrated circuits formed on the substrate.

Accordingly, a need exists for a method and apparatus for preventing etchant mist generation during edge bevel cleaning and more generally for preventing splashing by a fluid displaced from a substrate.

### SUMMARY OF THE INVENTION

In accordance with the present invention, methods and apparatus are provided for reducing or preventing fluid (e.g., an etching solution) displaced from a substrate from being splashed back on to and potentially damaging the substrate. In a first aspect of the invention, a system is provided that includes (1) a substrate support adapted to hold and rotate a substrate; (2) a source of fluid adapted to supply fluid to a surface of a substrate held by the substrate support; and (3) a shield positioned to capture fluid supplied by the source of fluid and displaced from a substrate held and rotated by the substrate support. The shield includes a radiused surface adapted to carry the captured fluid away from the substrate held by the substrate support.

In a second aspect of the invention, a system is provided that includes (1) a substrate support adapted to hold and rotate a substrate; (2) a nozzle adapted to supply fluid to an edge surface of a substrate held and rotated by the substrate support; and (3) a shield positioned to capture fluid supplied by the nozzle and displaced from a substrate held and rotated by the substrate support.

The shield includes a radiused surface adapted to carry the captured fluid away from the substrate held by the substrate support; and the radiused surface includes a first end and a second end. The shield is positioned so that when a substrate is held and rotated by the substrate support, the first end of the radiused surface is located at an elevation at least as high as that of the substrate and the second end of the radiused surface is located at a lower elevation than that of the substrate. The first end of the radiused surface also is located a smaller radial distance from the substrate than the second end of the radiused surface. Apparatus and methods in accordance with these and other aspects of the invention also are provided.

Other features and advantages of the present invention will become more fully apparent from the following detailed description, the appended claims and the accompanying drawings.

### BRIEF DESCRIPTION OF THE DRAWINGS

FIG. 1 is a cross sectional view, in pertinent part, of a substrate edge bevel cleaner chamber configured in accordance with the present invention;

FIGS. 2A-C illustrate a top plan view, a top perspective view and a bottom perspective view, respectively, of the radiused shield of FIG. 1; and

FIG. 3 is an enlarged, cross-sectional view of a portion of the chamber of FIG. 1 useful in describing the operation of the radiused shield of FIGS. 1-2C.

### DETAILED DESCRIPTION

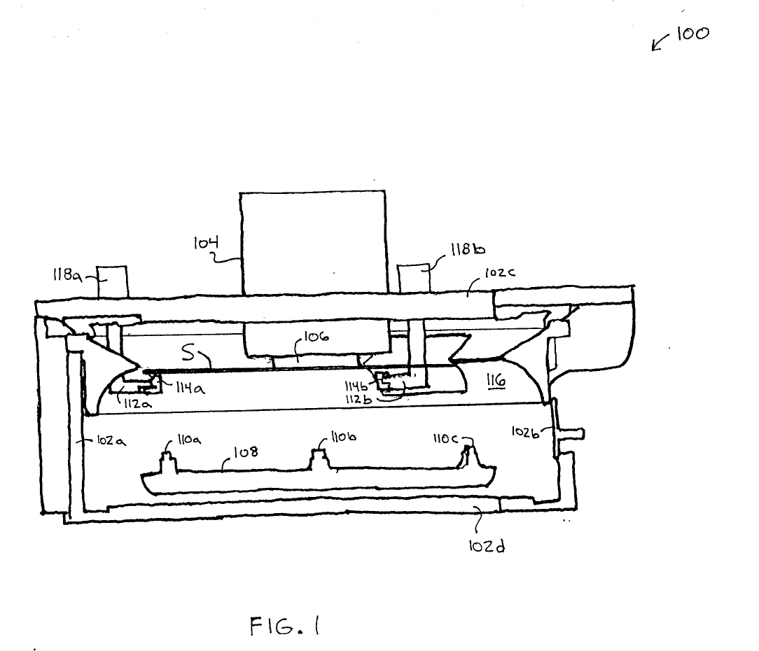

FIG. 1 is a cross sectional view, in pertinent part, of a substrate edge bevel cleaner chamber 100 configured in accordance with the present invention. The chamber 100 includes chamber sides 102a and 102b, chamber top 102c and chamber bottom 102d. The chamber 100 further includes a substrate support 104 that partially extends through the chamber top 102c and that is adapted to hold and rotate a substrate within the chamber 100. For example, the substrate support 104 may include a wafer chuck 106 having a wafer chucking surface (not shown) adapted to (1) hold a substrate thereagainst via vacuum, an electrostatic technique or some other conventional technique; and (2) rotate the substrate via a motor (not shown).

The chamber 100 further includes an exchange hoop 108 disposed near the bottom 102d of the chamber 100 that is adapted to receive a substrate to be processed within the chamber 100 (e.g., via a wafer handler (not shown)) and to hold the substrate so that the substrate support 104 may lower and retrieve the substrate as described further below. The exchange hoop 108 may have, for example, a plurality of support surfaces 110a-c adapted to hold a substrate (not shown) by its edges so that either a wafer handler (not shown) or the substrate support 104 may retrieve the substrate therefrom. More or fewer than three support surfaces may be employed.

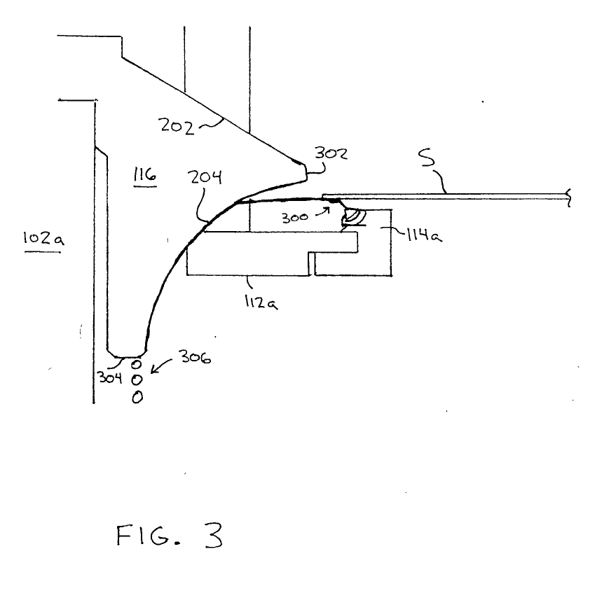

The chamber 100 also includes a plurality of dispenser arms 112a-b each having a nozzle 114a-b coupled thereto, and a radiused shield 116. Each nozzle 114a-b is adapted to spray a fluid (e.g., an etching solution) at an edge of a substrate S held and rotated by the substrate support 104 (as described below with reference to FIG. 3). Each dispenser arm 112a-b may be rotated (e.g., via a motor 118a-b) between a first position in which:

(1) the nozzle 114a-b is positioned below the substrate S;

(2) the nozzle 114a-b may supply fluid (e.g., an etching solution) to an edge surface of the substrate S; and

(3) the radiused shield 116 may capture fluid supplied by the nozzle 114a-b and displaced from the substrate S (as described below);

and a second position in which the nozzle 114a-b and the dispenser arm 112a-b are radially displaced from the substrate S so that the substrate S may be lowered below the nozzle 114a-b without contacting the nozzle 114a-b. With reference to FIG. 1, the first dispenser arm 112a is shown in the first position in which the nozzle 114a may supply fluid to an edge surface of the substrate S, and the second dispenser arm 112b is shown in the second position in which the substrate S may be lowered past the nozzle 114b without contacting the nozzle 114b (e.g., to load the substrate S into or out of the chamber 100). While two dispenser arms 112a-b and two nozzles 114a-b are shown in FIG. 1, it will be understood that more or fewer of each may be employed. In one particular embodiment, three dispenser arms and three nozzles are employed. Any conventional nozzles (e.g., jets, fluid stream dispensers, etc.) may be used with the chamber 100.

The angle that each dispenser arm 112a-b is rotated when moving between the first and second positions depends on several factors. For example, the length of each dispenser arm 112a-b, the angle of each nozzle 114a-b relative to each dispenser arm 112a-b, the rotational speed of the substrate S, the pressure of the fluid output by the nozzles 114a-b, etc., may affect this angle. In one embodiment of the invention, the angle between the first and second positions of each dispenser arm 112a-b is selected so that the fluid output by each nozzle 114a-b strikes the edge of the substrate S at an angle of about 30 degrees (relative to a tangent to the edge of the substrate S), and in the general direction that the substrate S rotates. That is, the angle at which fluid output by the nozzles 114a-b strikes the substrate S is determinative, rather than the angle between the first and second positions of the dispenser arms 112a-b.

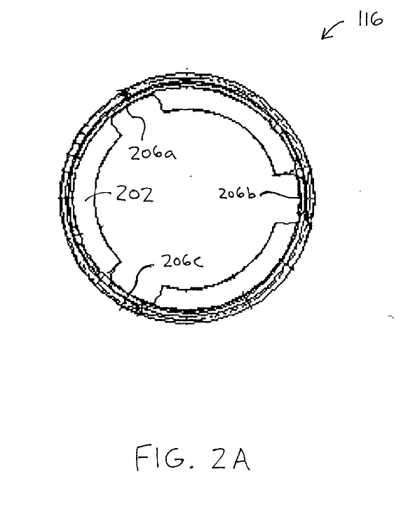

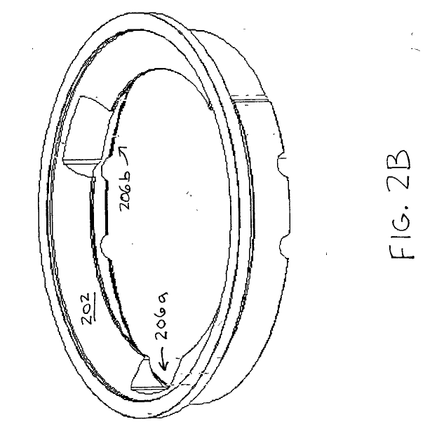

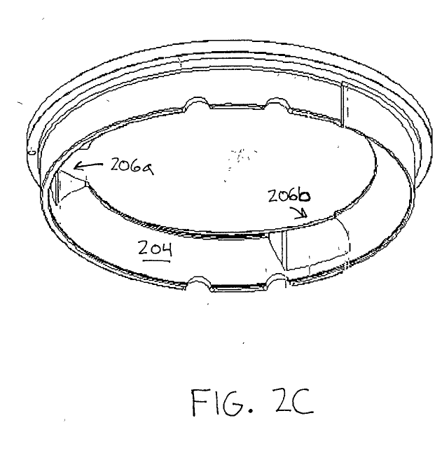

FIGS. 2A-C illustrate a top plan view, a top perspective view and a bottom perspective view, respectively, of the radiused shield 116 of FIG. 1. With reference to FIGS. 2A-C, the radiused shield 116 comprises a top, slated surface 202, a bottom, radiused surface 204 and a plurality of notches 206a-c formed therein. The radiused shield 116 may be fabricated (e.g., machined) from a single piece of material, or assembled from a number of components (e.g., the top and bottom surfaces 202, 204 may be separately formed and attached to one another by any known fastening technique).

In at least one embodiment, the radiused shield comprises polypropylene, although other materials such as high density polyethylene (HDPE), polyvinylidene fluoride (PVDF), perfluoroalkoxy (PFA), etc., may be similarly employed. As described further below, the radius of the radiused surface 204 is selected, and the shield 116 is positioned within the chamber 100, so that fluid displaced from the substrate S during edge bevel cleaning is captured by the shield 116 and is carried away from the substrate S before the fluid or its mist may splash back on to the substrate S. Damage to the substrate S due to displaced fluid thereby is reduced and/or eliminated. In one embodiment of the invention, the radius of the radiused surface 204 comprises about 42 mm. However, the selection of this radius depends on many factors such as the dimensions of the chamber 100, the pressure with which fluid is displaced from the substrate S by the nozzles 114a-b, the type of fluid sprayed by the nozzles 114a-b (e.g., the density/viscosity of the fluid), the rotation rate of the substrate S, the hydrophilic properties of the material that the shield 116 is made from, the distance between the edge of the substrate S and the radiused surface 204 of the shield 116, etc.

With reference to FIGS. 1-2C, the notches 206a-c are sized to receive the dispenser arms 112a-b and the nozzles 114a-b, and a third dispenser arm and nozzle (not shown) when the dispenser arms are in the “second” position. In general, the number of notches in the radiused shield 116 depends on the number of dispenser arms and nozzles employed.

FIG. 3 is an enlarged, cross-sectional view of a portion of the chamber 100 of FIG. 1 that shows the chamber wall 102a, the dispenser arm 112a, the nozzle 114a, the shield 116 and the substrate S, in pertinent part, and that is useful in describing the operation of the radiused shield 116. With reference to FIG. 3, when copper or another material is to be etched from the edge bevel (not shown) of the substrate S, the following steps may be performed:

(1) the substrate S is held by the substrate support 104 (e.g., so that the frontside or “device” side of the substrate S faces away from the substrate support 104);

(2) the arm 112a is placed in the “first” position as shown;

(3) the substrate S is rotated (e.g., via the substrate support 104); and

(4) the nozzle 114a sprays a fluid 300 (e.g., an etching solution) at the edge bevel of the substrate S.

The nozzle 114b similarly may be employed. In one embodiment of the invention (shown in FIG. 3), the shield 116 is positioned so that a first end 302 of the shield 116 is located at an elevation at least as high as that of the substrate S, and a second end 304 of the shield 116 is located at a lower elevation than that of the substrate S. The first end 302 also is located a smaller radial distance is from the substrate S than the second end 304. In this manner, fluid supplied by the nozzle 114a and displaced by the rotating substrate S is captured by the radiused surface 204 before it may splash on other chamber components (e.g., horizontally oriented components that may create a mist that may damage the substrate S). Because of the radiused shape of the radiused surface 204, the captured fluid flows along the radiused surface 204 (e.g., under the influence of gravity and surface tension) and harmlessly drips from the second end 304 of the shield 116 (as indicated by reference numeral 306). The fluid may be collected (via a bowl not shown) and drained from the chamber 100. Accordingly, fluid displaced from the substrate S is prevented from splashing back on to the substrate S and damaging the substrate S.

In at least one embodiment of the invention, the first end 302 and the second end 304 do not overlap the substrate S. In this manner, the substrate S may be raised above the shield 116 (if desired).

The overall operation of the chamber 100 will now be described with reference to FIGS. 1-3. To remove copper or some other material from an edge bevel of the substrate S, the substrate S is loaded into the chamber 100 and placed on the exchange hoop 108 (e.g., on the support surfaces 110a-c of the exchange hoop 108) via a wafer handler (not shown). The dispenser arms 112a-b rotate into the second position (e.g., into the notches 206a, 206b of the shield 116) so that the substrate support 104 may travel past the nozzles 114a-b without striking the nozzles, and the substrate support 104 lowers and retrieves the substrate from the exchange hoop 108 (e.g., via the wafer chuck 106). The substrate support 104 then raises the substrate S to a cleaning position (shown in FIG. 1 and FIG. 3) just below the first end 302 of the shield 116 (FIG. 3).

The dispenser arms 112a-b rotate into the first position so that the nozzles 114a-b are disposed underneath the substrate S and point toward the edge bevel of the substrate S. The substrate support 104 rotates the substrate S at a predetermined speed (e.g., about 700 r.p.m.), and the nozzles 114a-b spray etching solution (e.g., dilute sulfuric acid) at the edge bevel of the substrate S. A typical pressure at which the etching solution is delivered onto the substrate S is about 10-30 p.s.i., although other pressures may be used.

During spraying of the etching solution, etching solution strikes the substrate S, is displaced therefrom and is captured by the radiused surface 204 of the shield 116. The captured etching solution is harmlessly carried away from the substrate S toward the second end 304 of the shield 116 (e.g., before the etching solution can splash back on to the substrate S or create a mist that may damage the substrate S).

After the edge bevel of the substrate S has been cleaned, the substrate S may be rinsed (e.g., with deionized water). The dispenser arms 112a-b may again assume the second position, and the substrate support 104 may lower to the exchange hoop 108 and deposit the substrate S thereon. A wafer handler (not shown) thereafter may extract the substrate S and transfer the substrate S to another chamber (now shown) for further processing.

The foregoing description discloses only exemplary embodiments of the invention. Modifications of the above disclosed apparatus and method which fall within the scope of the invention will be readily apparent to those of ordinary skill in the art. For instance, while the radiused shield 116 has been described herein primarily within reference to preventing an etching solution sprayed on an edge bevel of a substrate from splashing back on to the substrate, it will be understood that the radiused shield 116 may be similarly employed to prevent any fluid displaced from a substrate (whether sprayed on an edge bevel or another substrate location) from splashing back on to the substrate. The dispenser arms 112a-b may be positioned so as to minimize the amount of splashing of fluid displaced from the substrate S. In at least one embodiment, the first end 302 of the shield 116 is positioned as close to the elevation of the substrate S as possible (e.g., while still reducing fluid from splashing back on to the substrate S).

Accordingly, while the present invention has been disclosed in connection with exemplary embodiments thereof, it should be understood that other embodiments may fall within the spirit and scope of the invention, as defined by the following claims.

The invention claimed is:

1. A system comprising:
a substrate support adapted to hold and rotate a substrate;
a source of fluid adapted to supply fluid to a surface of a substrate held by the substrate support; and
a shield positioned to capture fluid supplied by the source of fluid and displaced from a substrate held and rotated by the substrate support, the shield having a radiused surface adapted to carry the captured fluid away from the substrate held by the substrate support.

2. The apparatus of claim 1 wherein the radiused surface has a first end and a second end, and wherein the shield is positioned so that when a substrate is held and rotated by the substrate support:
the first end is located at an elevation at least as high as that of the substrate;
the second end is located at a lower elevation than that of the substrate; and
the first end is located a smaller radial distance from the substrate than the second end.

3. The apparatus of claim 2 wherein the shield is positioned so that the first and second ends do not overlap a substrate held and rotated by the substrate support.

4. The apparatus of claim 2 wherein the source of fluid is positioned so that when a substrate is held and rotated by the substrate support, the source of fluid supplies fluid to an edge surface of the surface.

5. The apparatus of claim 4 wherein the source of fluid comprises a nozzle.

6. The apparatus of claim 1 wherein the radiused surface is adapted to prevent fluid supplied by the source of fluid and displaced from a substrate held and rotated by the substrate support from splashing back onto the substrate.

7. The apparatus of claim 1 wherein the shield comprises a material selected from the group consisting of polypropylene, high density polyethylene, polyvinylidene fluoride, and perfluoroalkoxy.

8. The apparatus of claim 1 wherein the source of fluid is positioned so that when a substrate is held and rotated by the substrate support, the source of fluid is located at an elevation below that of the substrate.

9. The apparatus of claim 8 wherein the source of fluid is adapted to supply fluid to an edge surface of a substrate held and rotated by the substrate support.

10. The apparatus of claim 8 wherein the source of fluid comprises:
a nozzle; and
an arm coupled to the nozzle and adapted to assume:
a first position wherein:
the nozzle is positioned below a substrate held by the substrate support;
the nozzle supplies fluid to a surface of the substrate; and
the shield captures fluid supplied by the nozzle and displaced from the substrate; and
a second position wherein the nozzle and the arm are radially displaced from a substrate held by the substrate support so that the substrate may be lowered below the nozzle without contacting the nozzle.

11. The apparatus of claim 10 wherein the shield includes a notch sized to receive the nozzle and the arm when the arm is in the second position.

12. The apparatus of claim 1 wherein the substrate support comprises a vacuum surface adapted to contact a backside of a substrate and hold the substrate above the source of fluid while the substrate support rotates the substrate.

13. A system comprising:
a substrate support adapted to hold and rotate a substrate;
a nozzle adapted to supply fluid to an edge surface of a substrate held and rotated by the substrate support; and
a shield positioned to capture fluid supplied by the nozzle and displaced from a substrate held and rotated by the substrate support, the shield having a radiused surface adapted to carry the captured fluid away from the substrate held by the substrate support, wherein the radiused surface has a first end and a second end and wherein the shield is positioned so that when a substrate is held and rotated by the substrate support:
the first end is located at an elevation at least as high as that of the substrate;
the second end is located at a lower elevation than that of the substrate; and
the first end is located a smaller radial distance from the substrate than the second end.

14. The system of claim 13 further comprising an arm coupled to the nozzle and adapted to assume:
a first position wherein:
the nozzle is positioned below a substrate held by the substrate support;
the nozzle supplies fluid to an edge surface of the substrate; and
the shield captures fluid supplied by the nozzle and displaced from the substrate; and
a second position wherein the nozzle and the arm are radially displaced from a substrate held by the substrate support so that the substrate may be lowered below the nozzle without contacting the nozzle.

15. A method comprising:
supporting and rotating a substrate;
supplying fluid to a surface of the substrate while the substrate rotates;
capturing fluid displaced from the substrate via a radiused surface of a shield; and
carrying the captured fluid away from the substrate via the radiused surface.

16. The method of claim 15 wherein supplying fluid to a surface of the substrate comprises supplying fluid to an edge surface of the substrate.

17. The method of claim 16 wherein the fluid comprises an acid solution.

18. The method of claim 16 further comprising:
positioning a first end of the radiused surface at an elevation at least as high as that of the substrate; and
positioning a second end of the radiused surface at a lower elevation than that of the substrate.

19. The method of claim 15 wherein supplying fluid comprises spraying fluid via a nozzle positioned below the substrate.

20. The method of claim 19 further comprising radially displacing the nozzle from the substrate to allow the substrate to be raised or lowered without contacting the nozzle.

21. The method of claim 20 wherein radially displacing the nozzle comprises pivoting the nozzle into a notch of the shield.
